(19) United States
(12) Patent Application Publication
(10) Pub. No.: US 2007/0134828 A1
(43) Pub. Date: Jun. 14, 2007

(54) Method of producing semiconductor optical element

(75) Inventor: Masakazu Narita, Yokohama-shi (JP)

Correspondence Address: SMITH, GAMBRELL & RUSSELL, 1850 M STREET, N.W., SUITE 800, WASHINGTON, DC, 20036, US

(73) Assignee: SUMITOMO ELECTRIC INDUSTRIES, LTD.

(21) Appl. No.: 11/635,649

(22) Filed: Dec. 8, 2006

(30) Foreign Application Priority Data
Dec. 13, 2005 (JP) P2005-359040

(51) Int. Cl. H01L 21/00

(52) U.S. Cl. 438/22

(57) ABSTRACT

A production method of a semiconductor optical element includes: a step of forming an alignment mark on a laminate having an active layer comprised of a semiconductor; a step of forming a protective film on the alignment mark and forming an etching mask comprised of the same material as the protective film, on the laminate; a step of etching the laminate with the etching mask to form a mesa part; a step of forming a buried portion on a side face of the mesa part; a step of removing the etching mask while leaving the protective film, after the step of forming the buried portion; and a step of forming a semiconductor layer on the mesa part and on the buried portion, after the step of removing the etching mask.

### BACKGROUND OF THE INVENTION

1. Field of the Invention

The present invention relates to a method of producing a semiconductor optical element.

2. Related Background Art

In a production method of a semiconductor optical element, where alignment marks for lithography are formed on a semiconductor crystal, it is known that a protective film is formed on the alignment marks, in order to prevent deformation or damage of the alignment marks in process (cf. Japanese Patent Application Laid-Open No. 2001-251007).

On the other hand, for production of a semiconductor laser of a buried heterostructure (BH structure), there is a known method of forming a buried layer on a side face of a mesa part formed by etching and thereafter further forming a cladding layer and a contact layer on the mesa part and on the buried layer (cf. Japanese Patent No. 2827326). Specifically, first, an etching mask of stripe shape is formed on a multilayer substrate, and thereafter the multilayer substrate is etched using the etching mask, to form the mesa part of stripe shape. Thereafter, the buried layer is formed in the region removed by etching, using the etching mask as a selective growth mask. Furthermore, the etching mask is removed and thereafter the cladding layer and contact layer are formed on the mesa part and on the buried layer.

### SUMMARY OF THE INVENTION

The Inventors investigated a method of forming alignment marks and forming a protective film on the alignment marks, in the production of the semiconductor laser of the type described in Japanese Patent No. 2827326. However, it was found that when the etching mask and protective film were made of a single thin film, the protective film was also removed at the same time as the removal of the etching mask. This results in making the alignment marks exposed and thus the alignment marks could be buried or damaged during the formation of the cladding layer and contact layer.

The present invention has been accomplished in view of the above circumstances and an object of the invention is to provide a production method of a semiconductor optical element capable of preventing alignment marks from being buried or damaged.

In order to solve the above problem, a method of producing a semiconductor optical element according to the present invention comprises (a) a step of forming an alignment mark on a laminate comprising an active layer comprised of a semiconductor; (b) a step of forming a protective film on the alignment mark and forming an etching mask comprised of the same material as the protective film, on the laminate; (c) a step of etching the laminate with the etching mask to form a mesa part; (d) a step of forming a buried portion on a side face of the mesa part; (e) a step of removing the etching mask while leaving the protective film, after the step of forming the buried portion; and (f) a step of forming a semiconductor layer on the mesa part and on the buried portion, after the step of removing the etching mask.

### BRIEF DESCRIPTION OF THE DRAWINGS

FIG. 1 is a perspective view schematically showing a semiconductor optical element produced by production methods of a semiconductor optical element according to first and second embodiments.

FIG. 2A and FIG. 2B are drawings showing an example of arrangement of alignment marks.

FIGS. 3A to 3D are sectional views schematically showing respective steps in the production method of the semiconductor optical element according to the first embodiment.

FIGS. 4A to 4D are sectional views schematically showing respective steps in the production method of the semiconductor optical element according to the first embodiment.

FIGS. 5A to 5D are sectional views schematically showing respective steps in the production method of the semiconductor optical element according to the first embodiment.

FIGS. 6A to 6C are sectional views schematically showing respective steps in the production method of the semiconductor optical element according to the first embodiment.

FIGS. 7A to 7D are sectional views schematically showing respective steps in the production method of the semiconductor optical element according to the second embodiment.

FIGS. 8A to 8D are sectional views schematically showing respective steps in the production method of the semiconductor optical element according to the second embodiment.

FIGS. 9A to 9D are sectional views schematically showing respective steps in the production method of the semiconductor optical element according to the second embodiment.

FIGS. 10A to 10D are sectional views schematically showing respective steps in the production method of the semiconductor optical element according to the second embodiment.

FIGS. 11A to 11C are sectional views schematically showing respective steps in the production method of the semiconductor optical element according to the second embodiment.

### DESCRIPTION OF THE PREFERRED EMBODIMENTS

Embodiments of the present invention will be described below in detail with reference to the accompanying drawings. In the description of the drawings identical or equivalent elements will be denoted by the same reference symbols, without redundant description.

### First Embodiment

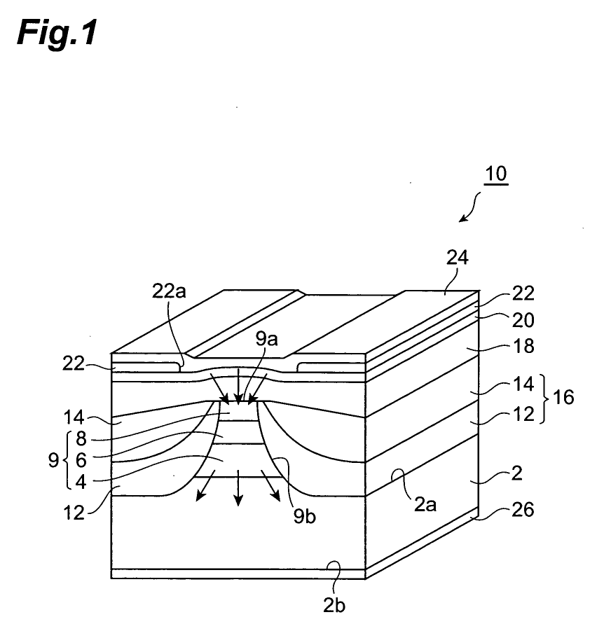

FIG. 1 is a perspective view schematically showing a semiconductor optical element produced by a production method of the semiconductor optical element according to the present embodiment. The semiconductor optical element 10 shown in FIG. 1 has the so-called buried heterostructure (BH structure). The semiconductor optical element 10 is, for example, a semiconductor laser used in the optical communication field. The semiconductor optical element 10 has a III-V compound semiconductor substrate 2 of a first conductivity type, and a mesa part 9 laid on a principal surface 2a of the III-V compound semiconductor substrate 2. The III-V compound semiconductor substrate 2 is, for example, an n-InP substrate.

The mesa part 9 has a buffer layer 4, an active layer 6, and a cladding layer 8 laid in the order named on the principal surface 2a of the III-V compound semiconductor substrate 2. The mesa part 9 preferably has a beltlike top surface 9a extending along a predetermined direction. The height of the mesa part 9 from the principal surface 2a is, for example, 2 μm. The buffer layer 4 is preferably a III-V compound semiconductor layer of the first conductivity type. The buffer layer 4 is, for example, an n-InP layer. The active layer 6 is preferably a III-V compound semiconductor layer and may have the quantum well structure. The active layer 6 is, for example, an i-GaInAsP layer. The cladding layer 8 is preferably a III-V compound semiconductor layer of a second conductivity type. The cladding layer 8 is, for example, a p-InP layer.

A buried portion 16 is placed so as to bury the mesa part 9, on a side face 9b of the mesa part 9. The buried portion 16 preferably has a III-V compound semiconductor layer 12 of the second conductivity type laid on the principal surface 2a of the III-V compound semiconductor substrate 2, and a III-V compound semiconductor layer 14 of the first conductivity type laid on the III-V compound semiconductor layer 12. The III-V compound semiconductor layer 12 is, for example, a p-InP layer. The III-V compound semiconductor layer 12 functions, for example, as a cladding layer. The III-V compound semiconductor layer 14 is, for example, an n-InP layer. The III-V compound semiconductor layer 14 functions, for example, as a carrier stop layer.

A cladding layer 18 and a contact layer 20 are provided in the order named, on the top surface 9a of the mesa part 9 and on the buried portion 16. The cladding layer 18 is preferably a III-V compound semiconductor layer of the second conductivity type. The cladding layer 18 is, for example, a p-InP layer. The contact layer 20 is preferably a III-V compound semiconductor layer of the second conductivity type. The contact layer 20 is, for example, a p⁺-GaInAs layer.

An insulating layer 22 with an aperture 22a is provided on the contact layer 20. The aperture 22a is preferably located above the top surface 9a of the mesa part 9. An electrode 24 electrically connected to the contact layer 20 is filled in the aperture 22a of the insulating layer 22. The electrode 24 has, for example, a Ti/Pt/Au structure. An electrode 26 is provided on a back surface 2b of the III-V compound semiconductor substrate 2. The electrode 26 has, for example, an AuGeNi/Au structure. When a voltage is applied between the electrodes 24, 26, an electric current is supplied to the active layer 6 whereupon light is emitted from an end face of the semiconductor optical element 10.

A production method of the semiconductor optical element 10 will be described below in detail, as an example of the production method of the semiconductor optical element according to the present embodiment.

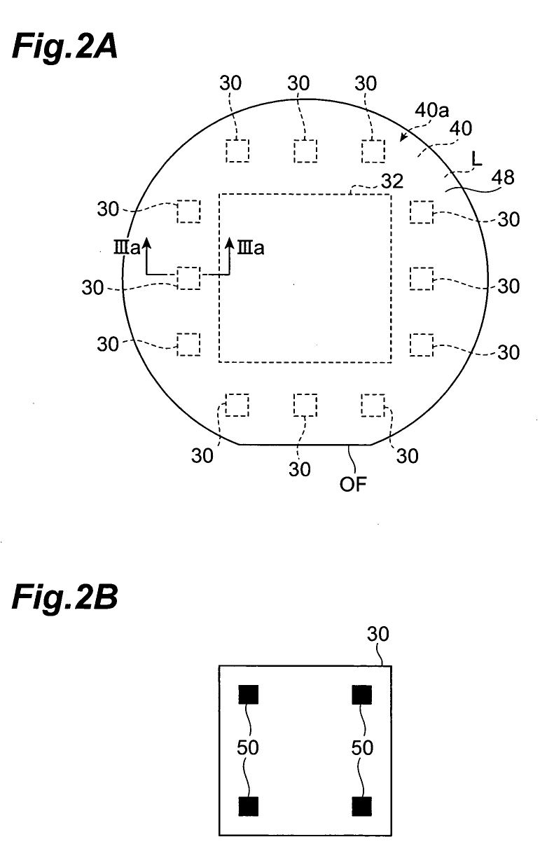

FIG. 2A is a plan view schematically showing an example of a laminate used for carrying out the production method of the semiconductor optical element according to the present embodiment. The laminate L shown in FIG. 2A is one in which a plurality of semiconductor layers are laid on a III-V compound semiconductor substrate 40. A cap layer 48 is preferably provided on the laminate L.

An orientation flat OF is formed in the peripheral edge of the III-V compound semiconductor substrate 40. A pattern region 32 for fabrication of a plurality of semiconductor optical elements arranged in a matrix pattern is preferably provided in the central region of a principal surface 40a of the III-V compound semiconductor substrate 40. A plurality of alignment mark pattern regions 30 for formation of after-described alignment marks (marks for registration) 50 are preferably provided so as to surround the pattern region 32, in the peripheral region of the principal surface 40a of the III-V compound semiconductor substrate W.

FIG. 2B is an illustration schematically showing an example of the alignment mark pattern regions. A plurality of alignment marks 50 arranged in a matrix pattern are placed in an alignment mark pattern region 30 shown in FIG. 2B.

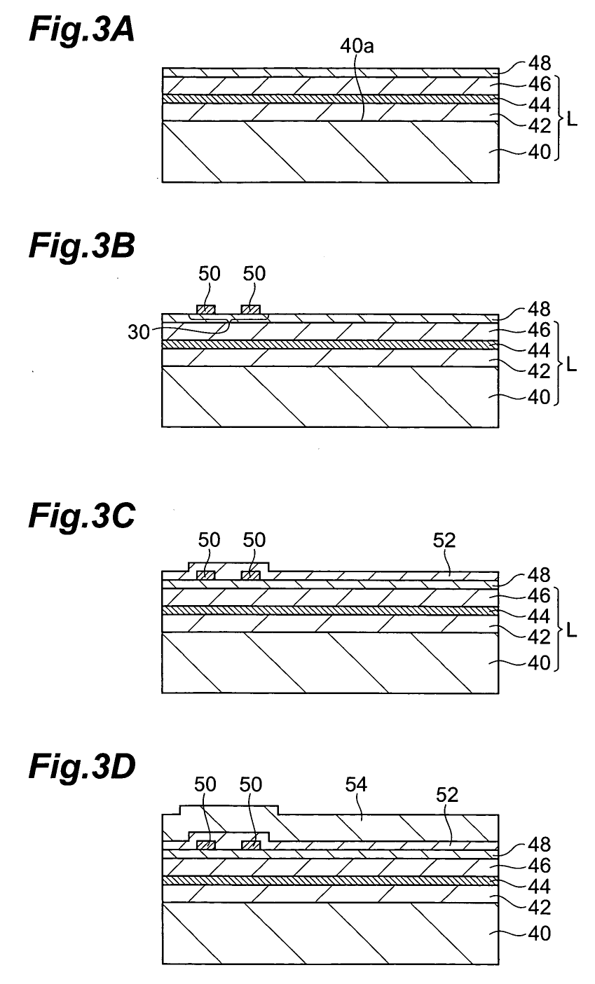

FIGS. 3A to 3D, FIGS. 4A to 4D, FIGS. 5A to 5D, and FIGS. 6A to 6C are sectional views schematically showing respective steps in the production method of the semiconductor optical element according to the present embodiment. FIG. 3A is a sectional view along line IIIa-IIIa in FIG. 2A. The production method of the semiconductor optical element according to the present embodiment is preferably carried out, for example, in the following order.

(Alignment Mark Forming Step)

As shown in FIGS. 3A and 3B, alignment marks 50 are formed on a laminate L including an active layer 44 comprised of a semiconductor. The laminate L preferably has a III-V compound semiconductor substrate 40 of the first conductivity type, a buffer layer 42 laid on a principal surface 40a of the III-V compound semiconductor substrate 40, an active layer 44 laid on the buffer layer 42, and a cladding layer 46 laid on the active layer 44. A cap layer 48 is preferably provided between the cladding layer 46 and the alignment marks 50. The III-V compound semiconductor substrate 40, the buffer layer 42, the active layer 44, and the cladding layer 46 are parent bodies of the III-V compound semiconductor substrate 2, the buffer layer 4, the active layer 6, and the cladding layer 8, respectively. The cap layer 48 is preferably a III-V compound semiconductor layer of the second conductivity type. The cap layer 48 is, for example, a p-InGaAs layer.

The alignment marks 50 are formed, for example, as described below. First, an insulating film (not shown), e.g., a silicon nitride film (SiN film) or a silicon oxide film (SiO₂ film) in the thickness of 50-500 nm, is formed on the laminate L. Thereafter, a photoresist layer (not shown) is formed on the insulating film. Furthermore, exposure of the photoresist layer is carried out using a photomask (not shown) corresponding to the shapes of the alignment marks 50. The exposed photoresist layer is developed to form a resist pattern (not shown). Subsequently, using the resist pattern as an etching mask, the insulating film is etched, for example, with a hydrofluoric acid-based etchant (BHF solution or HF solution). The insulating film may be etched by dry etching. Thereafter, the resist pattern is removed, for example, with an oxygen plasma to form the alignment marks 50 of the insulating film.

(Protective Film and Etching Mask Forming Step)

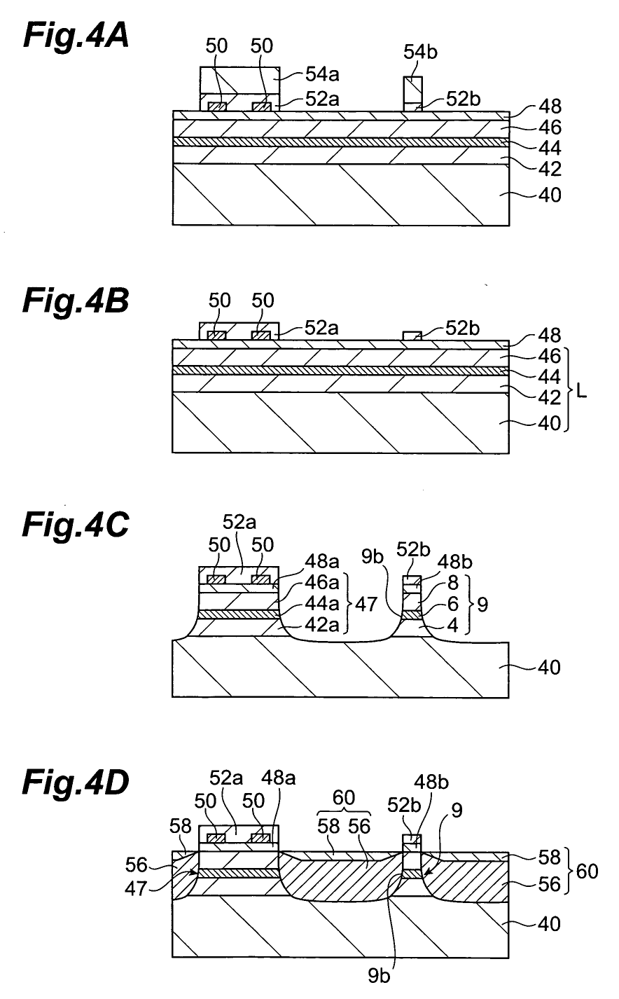

As shown in FIGS. 3C, 3D, 4A, and 4B, a protective film 52a is formed on the alignment marks 50 and an etching mask 52b comprised of the same material as the protective film 52a is formed on the laminate L. The protective film 52a may be comprised of the same material as the alignment marks 50, or may be comprised of a different material. The protective film 52a and the etching mask 52b are arranged alongside on the laminate L.

The protective film 52a and etching mask 52b are formed, for example, as described below. First, as shown in FIG. 3C, an insulating film 52, e.g., a silicon nitride film or a silicon oxide film in the thickness of 50-500 nm, is formed so as to cover the alignment marks 50, on the laminate L.

After that, as shown in FIG. 3D, a photoresist layer 54 is formed on the insulating film 52. Furthermore, exposure of the photoresist layer 54 is carried out using a photomask corresponding to the shapes of the protective film 52a and etching mask 52b. The shape of the etching mask 52b is, for example, a stripe shape.

The exposed photoresist layer 54 is developed to form a resist pattern 54a corresponding to the shape of the protective film 52a and a resist pattern 54b corresponding to the shape of the etching mask 52b, as shown in FIG. 4A. Using the resist patterns 54a, 54b as an etching mask, the insulating film 52 is etched, for example, with a hydrofluoric acid-based etchant (BHF solution or HF solution). The insulating film 52 may be etched by dry etching.

Thereafter, the resist patterns 54a, 54b are removed to form the protective film 52a and etching mask 52b comprised of the insulating film, as shown in FIG. 4B. When the protective film 52a and alignment marks 50 are made of the same material, surfaces of the alignment marks 50 are preferably modified, for example, with an oxygen plasma or the like, in terms of improvement in visibility.

(Mesa Part Forming Step)

As shown in FIG. 4C, a mesa part 9 is formed by etching the laminate L, using the etching mask 52b. The laminate L is etched, for example, with an etchant such as a compound liquid of bromine (Br) and methanol. The laminate L may be etched by dry etching.

The protective film 52a also functions as an etching mask in the same manner as the etching mask 52b, and thus a mesa part 47 is formed. The mesa part 47 has a buffer layer 42a made from the buffer layer 42, an active layer 44a made from the active layer 44, and a cladding layer 46a made from the cladding layer 46.

The cap layer 48 is also etched by the etching. It results in forming a cap layer 48a made from the cap layer 48, between the mesa part 47 and the alignment marks 50 and forming a cap layer 48b made from the cap layer 48, between the mesa part 9 and the etching mask 52b.

(Buried Portion Forming Step)

As shown in FIG. 4D, a buried portion 60 is formed on a side face 9b of the mesa part 9. The buried portion 60 has a III-V compound semiconductor layer 56 of the second conductivity type laid on the III-V compound semiconductor substrate 40, and a III-V compound semiconductor layer 58 of the first conductivity type laid on the III-V compound semiconductor layer 56. The III-V compound semiconductor layers 56, 58 are parent bodies of the III-V compound semiconductor layers 12, 14, respectively.

(Cap Layer Forming Step)

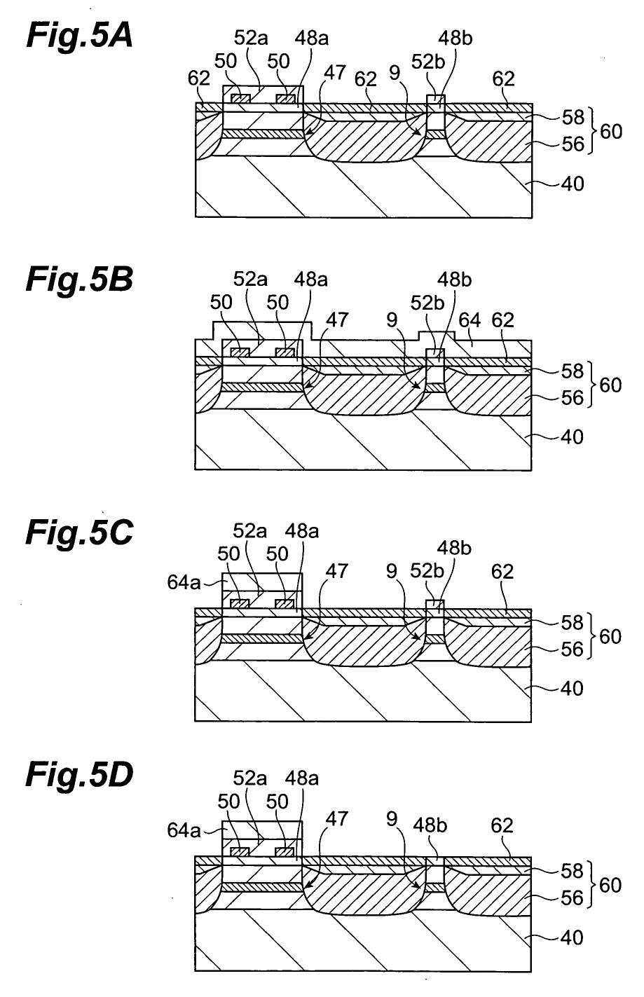

As shown in FIG. 5A, a cap layer 62 is preferably formed on the buried portion 60. The cap layer 62 is preferably a III-V compound semiconductor layer of the second conductivity type. The cap layer 62 is, for example, a p-InGaAs layer. The cap layer 62 can prevent the buried portion 60 from being contaminated or damaged in an after-described etching mask removing step.

(Etching Mask Removing Step)

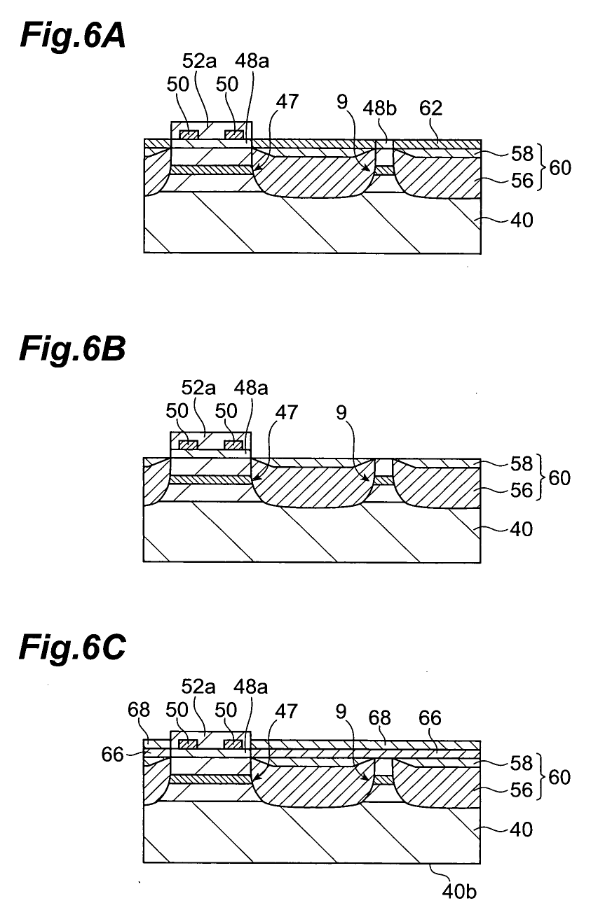

As shown in FIGS. 5B-5D and 6A, the etching mask 52b is selectively removed while leaving the protective film 52a.

The etching mask 52b is removed, for example, as described below. First, as shown in FIG. 5B, a photoresist layer 64 is formed so as to cover the protective film 52a and the etching mask 52b.

Thereafter, photolithography is used to effect exposure and development of the photoresist layer 64, to form a resist pattern 64a on the protective film 52a, as shown in FIG. 5C.

Furthermore, as shown in FIG. 5D, the etching mask 52b is removed, for example, with a hydrofluoric acid-based etchant (BHF solution or HF solution) that can dissolve the etching mask 52b. At this time, the resist pattern 64a functions as an etching mask and thus the protective film 52a is not etched.

Subsequently, as shown in FIG. 6A, the resist pattern 64a is removed.

(Cap Layer Removing Step)

As shown in FIG. 6B, the cap layers 62, 48b are removed. The cap layers 62, 48b are removed, for example, with phosphoric acid (H₃PO₄) or the like. This can reduce influence on crystal growth in an after-described semiconductor layer forming step.

(Semiconductor Layer Forming Step)

As shown in FIG. 6C, a cladding layer 66 (semiconductor layer) is formed on the mesa part 9 and on the buried portion 60. Thereafter, a contact layer 68 is formed on the cladding layer 66. The cladding layer 66 and the contact layer 68 are parent bodies of the cladding layer 18 and the contact layer 20, respectively.

(Insulating Layer and Electrode Forming Step)

An insulating layer (not shown) with an aperture as a parent body of the insulating layer 22 is formed on the contact layer 68, and a first electrode (not shown) as a parent body of the electrode 24 is formed so as to fill the aperture. A second electrode (not shown) as a parent body of the electrode 26 is formed on the back surface 40b of the III-V compound semiconductor substrate 40. Thereafter, the III-V compound semiconductor substrate 40 is diced to obtain a plurality of semiconductor optical elements 10 as shown in FIG. 1.

In the production method of the semiconductor optical element of the present embodiment, the protective film 52a remains without being removed, in the removal of the etching mask 52b. It prevents the simultaneous removal of the protective film 52a. This can prevent the alignment marks 50 from being lost, buried, or damaged, during the formation of the cladding layer 66 and contact layer 68. By using the alignment marks 50, the alignment accuracy can be improved in processes using photolithography. For example, when a stepper is used, the alignment accuracy of ±0.1 μm is achieved. As a result, semiconductor optical elements 10 can be produced in a higher density.

As the cap layer 62 is formed, the cap layer 62 protects the buried portion 60 in the removal of the etching mask 52b, whereby the buried portion 60 can be prevented from being contaminated or damaged. Therefore, defects are reduced in the buried portion 60, so as to improve the efficiency of light emission of the semiconductor optical element 10.

Furthermore, since the alignment marks 50 are comprised, for example, of the insulating film such as a silicon nitride film or silicon oxide film, it becomes easier to form the alignment marks 50. When a failure occurs in formation of an alignment mark, the defective alignment mark can be removed and a new alignment mark can be formed.

### Second Embodiment

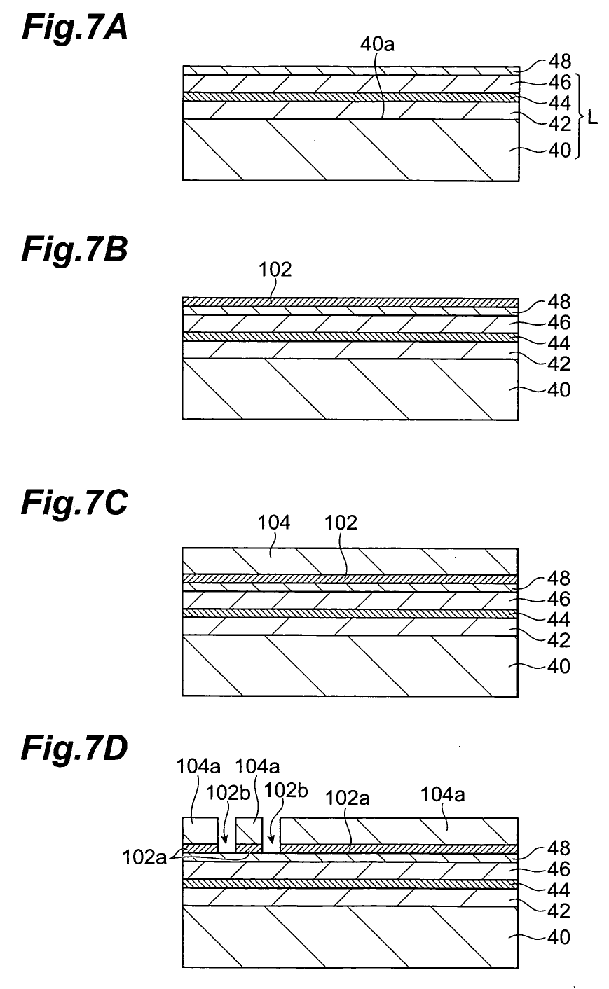

FIGS. 7A to 7D, FIGS. 8A to 8D, FIGS. 9A to 9D, FIGS. 10A to 10D, and FIGS. 11A to 11C are sectional views schematically showing respective steps in the production method of the semiconductor optical element according to the present embodiment. FIG. 7A is a sectional view along line IIIa-IIIa in FIG. 2A. The production method of the semiconductor optical element according to the present embodiment is preferably carried out, for example, in the following order.

(Alignment Mark Forming Step)

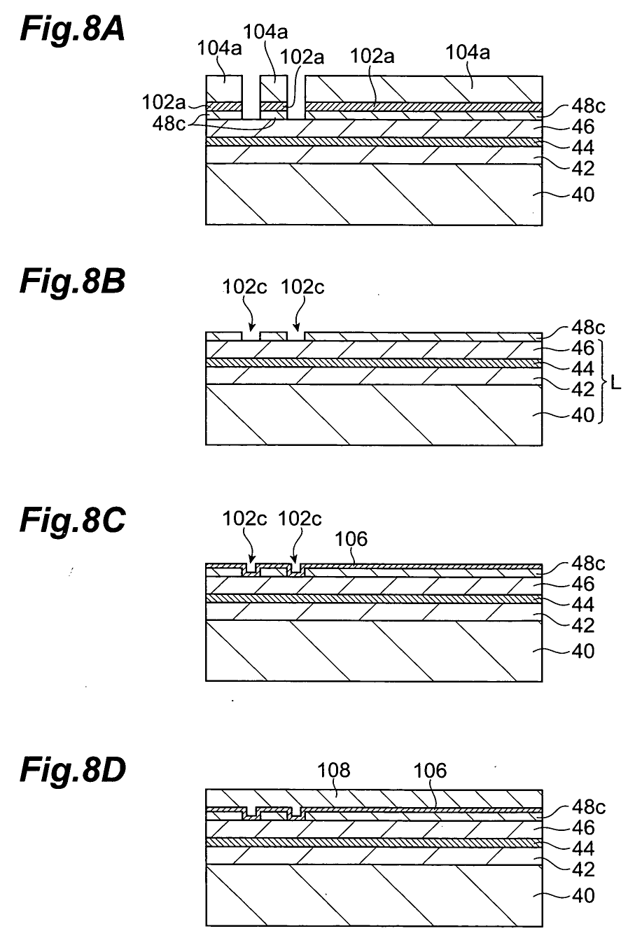

As shown in FIGS. 7A-7D, 8A, and 8B, alignment marks 102c are formed on the laminate L including the active layer 44. The alignment marks 102c are comprised of depressions.

The alignment marks 102c are formed, for example, as described below. First, as shown in FIGS. 7A and 7B, an insulating film 102, e.g., a silicon nitride film (SiN film) or a silicon oxide film (SiO₂ film) in the thickness of 50-500 nm, is formed on the laminate L.

After that, as shown in FIG. 7C, a photoresist layer 104 is formed on the insulating film 102. Furthermore, exposure of the photoresist layer 104 is performed using a photomask (not shown) corresponding to the shapes of the alignment marks 102c.

The exposed photoresist layer 104 is developed to form a resist pattern 104a, as shown in FIG. 7D. Subsequently, using the resist pattern 104a as an etching mask, the insulating film 102 is etched, for example, with a hydrofluoric acid-based etchant (BHF solution or HF solution) to form an insulating film pattern 102a with apertures 102b corresponding to the alignment marks 102c. The insulating film 102 may be etched by dry etching to form the insulating film pattern 102a.

Subsequently, as shown in FIG. 8A, the cap layer 48 is etched using the insulating film pattern 102a as an etching mask, to form a patterned cap layer 48c. An etchant herein is, for example, a compound liquid of phosphoric acid (H₃PO₄), hydrogen peroxide (H₂O₂), and water (H₂O). When the cladding layer 46 is an InP layer, the cladding layer 46 functions as an etch stop layer.

After the resist pattern 104a is removed, the insulating film pattern 102a is removed, for example, with a hydrofluoric acid-based etchant (BHF solution or HF solution) to form alignment marks 102c, as shown in FIG. 8B.

The resist pattern 104a may be removed before the etching of the cap layer 48. It is also possible to form the photoresist layer 104 on the cap layer 48, without use of the insulating film 102, and to form the alignment marks 102c, using the photoresist pattern 104a.

(Protective Film and Etching Mask Forming Step)

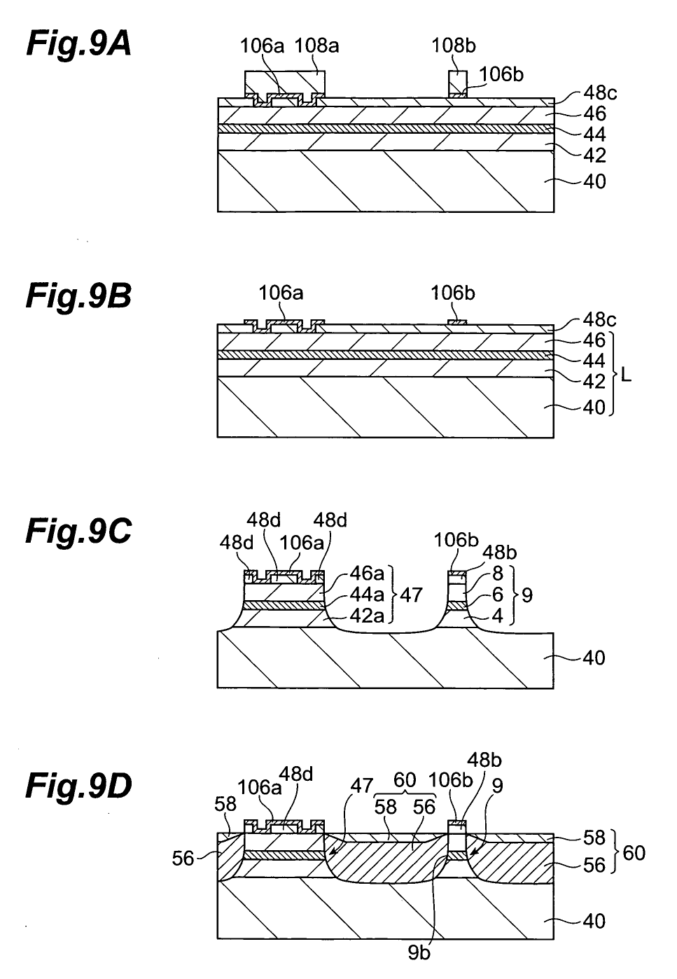

As shown in FIGS. 8C, 8D, 9A, and 9B, a protective film 106a is formed on the alignment marks 102c and an etching mask 106b comprised of the same material as the protective film 106a is formed on the laminate L.

The protective film 106a and etching mask 106b are formed, for example, as described below. First, as shown in FIG. 8C, an insulating film 106, e.g., a silicon nitride film or a silicon oxide film in the thickness of 50-500 nm, is formed so as to cover the alignment marks 102c, on the laminate L.

After that, as shown in FIG. 8D, a photoresist layer 108 is formed on the insulating film 106. Furthermore, exposure of the photoresist layer 108 is performed using a photomask corresponding to the shapes of the protective film 106a and etching mask 106b. The shape of the etching mask 106b is, for example, a stripe shape.

The exposed photoresist layer 108 is developed to form a resist pattern 108a corresponding to the shape of the protective film 106a and a resist pattern 108b corresponding to the shape of the etching mask 106b, as shown in FIG. 9A. Using the resist patterns 108a, 108b as an etching mask, the insulating film 106 is etched, for example, with a hydrofluoric acid-based etchant (BHF solution or HF solution). This results in forming the protective film 106a and etching mask 106b comprised of the insulating film. The insulating film 106 may be etched by dry etching.

Thereafter, as shown in FIG. 9B, the resist patterns 108a, 108b are removed.

(Mesa Part Forming Step)

As shown in FIG. 9C, the laminate L is etched using the etching mask 106b, to form the mesa part 9. The laminate L is etched, for example, with an etchant such as a compound liquid of bromine (Br) and methanol. The laminate L may be etched by dry etching.

Since the protective film 106a also functions as an etching mask in the same manner as the etching mask 106b, a mesa part 47 is formed. The cap layer 48 is also etched by the etching. It results in forming a cap layer 48d made from the cap layer 48, between the mesa part 47 and the protective film 106a and forming a cap layer 48b made from the cap layer 48, between the mesa part 9 and the etching mask 106b.

(Buried Portion Forming Step)

As shown in FIG. 9D, the buried portion 60 is formed on the side face 9b of the mesa part 9.

(Cap Layer Forming Step)

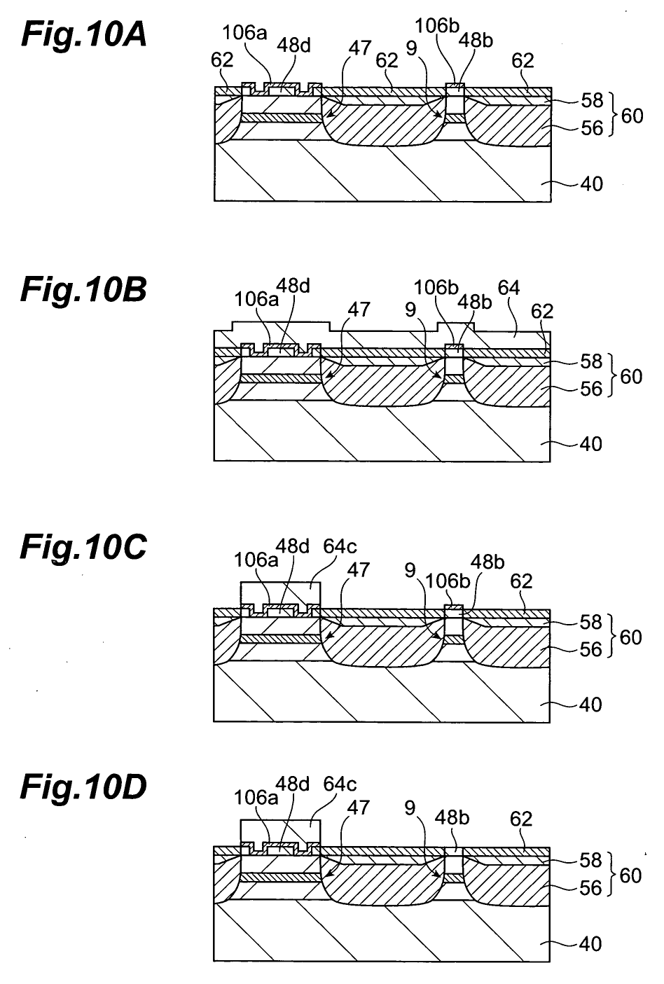

As shown in FIG. 10A, a cap layer 62 is preferably formed on the buried portion 60.

(Etching Mask Removing Step)

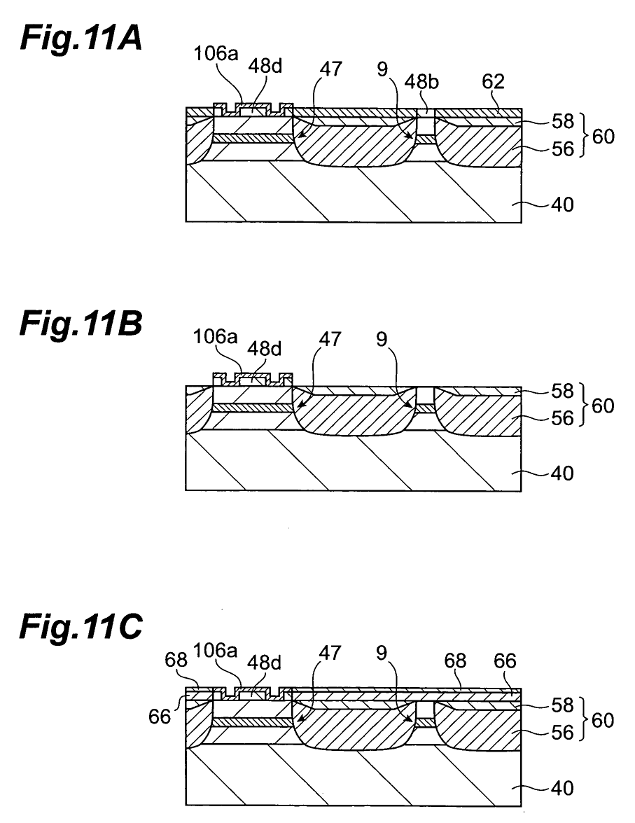

As shown in FIGS. 10B-10D and 11A, the etching mask 106b is selectively removed while leaving the protective film 106a.

The etching mask 106b is removed, for example, as described below. First, as shown in FIG. 10B, a photoresist layer 64 is formed so as to cover the protective film 106a and etching mask 106b.

After that, photolithography is used to effect exposure and development of the photoresist layer 64, to form a resist pattern 64c on the protective film 106a, as shown in FIG. 10C.

Furthermore, as shown in FIG. 10D, the etching mask 106b is removed, for example, with a hydrofluoric acid-based etchant (BHF solution or HF solution) that can dissolve the etching mask 106b. At this time, the resist pattern 64c functions as an etching mask, and thus the protective film 106a is not etched.

Subsequently, as shown in FIG. 11A, the resist pattern 64c is removed.

(Cap Layer Removing Step)

As shown in FIG. 11B, the cap layers 62, 48b are removed.

(Semiconductor Layer Forming Step)

As shown in FIG. 11C, the cladding layer 66 is formed on the mesa part 9 and on the buried portion 60. Thereafter, the contact layer 68 is formed on the cladding layer 66.

(Insulating Layer and Electrode Forming Step)

A plurality of semiconductor optical elements 10 as shown in FIG. 1 are obtained by a method similar to that in the first embodiment.

In the production method of the semiconductor optical element of the present embodiment, the protective film 106a remains without being removed, in the removal of the etching mask 106b. Therefore, the protective film 106a is prevented from being simultaneously removed. For this reason, it is feasible to prevent the alignment marks 102c from being lost, buried, or damaged, during the formation of the cladding layer 66. By using the alignment marks 102c, the alignment accuracy can be improved in processes using photolithography. For example, when a stepper is used, the alignment accuracy of ±0.1 μm is achieved. As a result, semiconductor optical elements 10 can be produced in a higher density.

As the cap layer 62 is formed, the cap layer 62 protects the buried portion 60 in the removal of the etching mask 106b, whereby the buried portion 60 can be prevented from being contaminated or damaged.

The preferred embodiments of the present invention were described above in detail, but it is noted that the present invention is by no means limited to each of the above embodiments. For example, the cap layer 62 is not essential. The alignment marks 50 may be comprised of a semiconductor film, instead of the insulating film.

As described above, the present invention provides the production method of the semiconductor optical element capable of preventing the alignment marks from being buried or damaged.

What is claimed is:

1. A method of producing a semiconductor optical element, comprising:
a step of forming an alignment mark on a laminate comprising an active layer comprised of a semiconductor;
a step of forming a protective film on the alignment mark and forming an etching mask comprised of the same material as the protective film, on the laminate;
a step of etching the laminate with the etching mask to form a mesa part;
a step of forming a buried portion on a side face of the mesa part;
a step of removing the etching mask while leaving the protective film, after the step of forming the buried portion; and
a step of forming a semiconductor layer on the mesa part and on the buried portion, after the step of removing the etching mask.

2. The method according to claim 1, further comprising:
a step of forming a cap layer on the buried portion, after the step of forming the buried portion and before the step of removing the etching mask; and
a step of removing the cap layer, after the step of removing the etching mask and before the step of forming the semiconductor layer.

3. The method according to claim 1, wherein the alignment mark is comprised of an insulating film.
